(19) United States
(12) Patent Application Publication
(10) Pub. No.: US 2007/0257323 A1
(43) Pub. Date: Nov. 8, 2007

(54) Stacked contact structure and method of fabricating the same

(75) Inventors: Ren-Fen Tsui, Taipei (TW); Jiaw-Ren Shih, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/418,232

(22) Filed: May 5, 2006

(51) Int. Cl. H01L 29/76

(52) U.S. Cl. 257/382

(57) ABSTRACT

A stacked contact structure includes a first contact plug of a first conductive material filling a first contact hole in a first dielectric layer, and a second contact plug of a second conductive material filling a second contact hole in a second dielectric layer. The second conductive material is different from the first conductive material, and the second conductive material has an electrical resistance lower than that of the first conductive material.

### TECHNICAL FIELD

The present invention relates to semiconductor fabrication, and particularly to a stacked contact structure and methods of fabricating the same.

### BACKGROUND

Electrically conductive lines providing, for example, signal transfer are essential in electronic devices as well as semiconductor integrated circuit (IC) devices. The conductive lines on different levels are connected through conductive plugs in required position to provide a predetermined function. Continuing advances in semiconductor manufacturing processes have resulted in semiconductor devices with finer features and/or higher degrees of integration. Among the various features included within a semiconductor device, contact structures typically provide an electrical connection between circuit devices and/or interconnection layers.

A typical contact structure may include forming a contact hole in an interlevel dielectric (ILD) and then filling such a contact hole with a conductive material, for example, a tungsten contact, however, providing disadvantageously high resistance. The contact height is defined by the thickness of the ILD that separates the two levels in the circuit, such as the substrate and higher wiring levels. Unfortunately, while the contact width continually decreases, the contact height cannot decrease proportionately. The contact aspect ratio continues to increase, causing difficulties in metal filling process.

It is therefore desirable to provide a novel contact structure and fabrication methods for improving the process window of the tungsten contact and reducing the contact resistance.

### SUMMARY OF THE INVENTION

Embodiments of the present invention include stacked contact structures and method of forming the same, which employ a contact plug of a relatively higher resistance stacked by a second contact plug of a relatively lower resistance for improving resistance/capacitance coupling (RC delay).

In one aspect, the present invention provides a stacked contact structure for a semiconductor device. The semiconductor device has a gate structure on a semiconductor substrate and a source/drain region laterally adjacent to the gate structure in the semiconductor substrate. A first dielectric layer is formed overlying the gate structure and the source/drain region, and has a first contact hole over at least one of the gate structure and the source/drain region. A first contact plug is formed of a first conductive material filling the first contact hole, and is electrically coupled to at least one of the gate structure and the source/drain region. A second dielectric layer is formed overlying the first dielectric layer and the first contact plug, and has a second contact hole exposing the first contact plug. A second contact plug is formed of a second conductive material filling the second contact hole, and is electrically coupled to the first contact plug. The second conductive material is different from the first conductive material, and the second conductive material has an electrical resistance lower than that of the first conductive material.

In another aspect, the present invention provides a stacked contact structure for a semiconductor device. The semiconductor device has a gate structure on a semiconductor substrate and source/drain regions laterally adjacent to the gate structure in the semiconductor substrate. A first dielectric layer is formed overlying the gate structure and the source/drain regions, and has a first contact hole over at least one of the gate structure and the source/drain regions. A tungsten plug is formed in the first contact hole and electrically coupled to at least one of the gate structure and the source/drain regions. A second dielectric layer is formed overlying the first dielectric layer and the first contact plug, and has a second contact hole exposing the tungsten plug. A copper plug is formed in the second contact hole and electrically coupled to the tungsten plug. An interconnection structure is formed overlying the second dielectric layer and electrically coupled to the copper plug.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1A to FIG. 1D are cross-sectional diagrams illustrating an exemplary embodiment of a method of forming a stacked contact structure using a tungsten plug stacked by a copper plug for electrically coupling source/drain regions;

FIG. 2 is a cross-sectional diagram illustrating an exemplary embodiment of a stacked contact structure using a tungsten plug stacked by a copper plug for electrically coupling the gate electrode layer and the source/drain regions;

FIG. 3A is a cross-sectional diagram illustrating an exemplary embodiment of a stacked contact structure using a tungsten plug stacked by a dual-damascene copper plug for electrically coupling the source/drain regions; and

FIG. 3B is a cross-sectional diagram illustrating an exemplary embodiment of a stacked contact structure using a tungsten plug stacked by a dual-damascene copper plug for electrically coupling the gate electrode layer and the source/drain regions.

### DETAILED DESCRIPTION OF ILLUSTRATIVE EMBODIMENTS

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

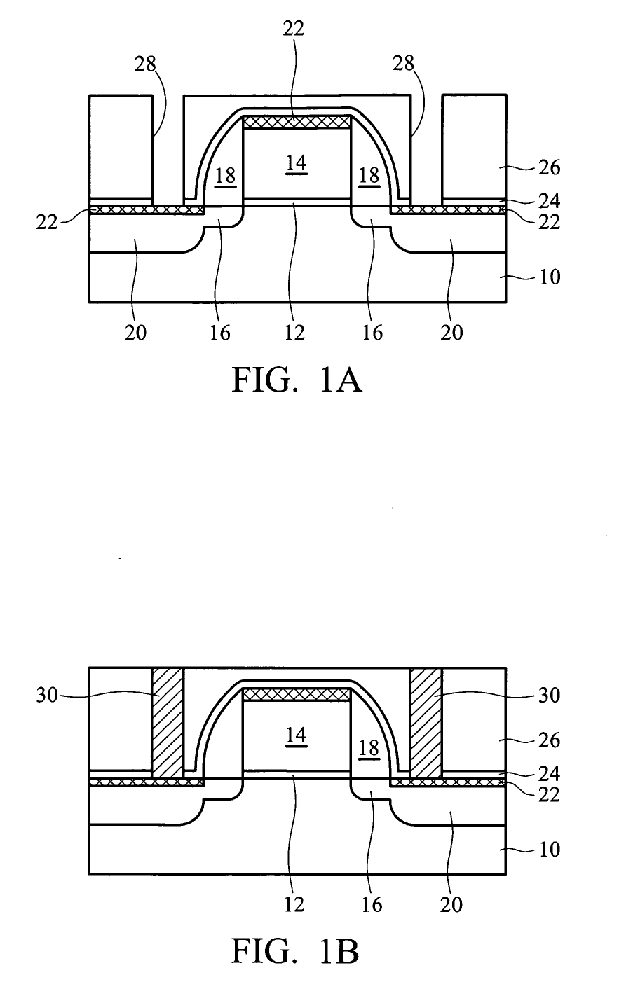

Herein, cross-sectional diagrams of FIG. 1A to 1D illustrate an exemplary embodiment of a method of forming a stacked contact structure using a tungsten plug stacked by a copper plug for electrically coupling source/drain regions.

In FIG. 1A, a gate dielectric material and a gate conductive material deposited on a semiconductor substrate 10 are patterned and respectively become a gate dielectric layer 12 and a gate electrode layer 14, both of which form together as a gate structure. The substrate 10 is bulk silicon, but other commonly used materials and structures such as silicon on insulator (SOI) or a silicon layer overlying a bulk silicon germanium may also be used. The gate dielectric layer 12 may be formed of silicon oxide or a high-k dielectric material. The gate electrode layer 14 may be formed of amorphous polysilicon, doped polysilicon, metal, single crystalline silicon or other conductive materials.

A light ion implantation process is then performed to form two lightly doped regions 16 respectively at each side of the gate structure in the substrate 10. Next, a dielectric spacer 18 is formed on each sidewall of the gate structure. The dielectric spacer 18 may be formed of oxide, nitride, oxynitride, or combinations thereof. A heavy ion implantation process is then performed to form a heavily doped region 20 on the lightly doped region 16. Thus, two source/drain regions 20 with a lightly doped drain (LDD) structure 16 are formed in the substrate 10 at each side of the gate structure. Whether a MOS transistor is nMOS or pMOS will depend on the conductivity type of the substrate 10 and the source/drain regions 20. For pMOS transistors, the LDD structure and the source/drain regions will be p-type and the substrate will be n-type. For nMOS transistors, the LDD structure and the source/drain regions will be n-type and the substrate will be p-type.

In order to reduce sheet resistance, a silicide layer 22 is formed on the source/drain regions 20 and the gate electrode layer 14. The silicide layer 22 is a metal silicide layer comprising metals such as titanium, cobalt, nickel, palladium, platinum, erbium, and the like.

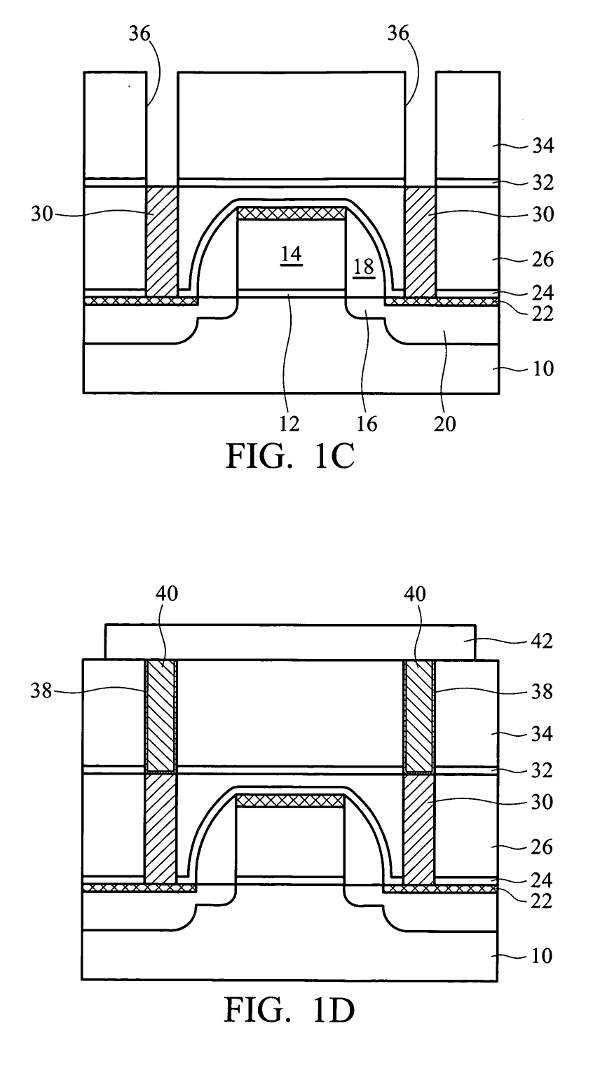

A contact etch stop layer (CESL) 24 for controlling the end point during subsequent contact hole formation is deposited on the above-described MOS transistor completed on the substrate 10. The CESL 24 may be formed of silicon nitride, silicon oxynitride, silicon carbide, or combinations thereof. A first inter-layered dielectric (ILD) layer 26 is formed on the CESL 24 so as to isolate the MOS transistor from a subsequent formation of an interconnect structure. The first ILD layer 26 may be a silicon oxide containing layer formed of doped or undoped silicon oxide by a thermal CVD process or high-density plasma (HDP) process, e.g., undoped silicate glass (USG), phosphorous doped silicate glass (PSG) or borophosphosilicate glass (BPSG). Alternatively, the first ILD layer 26 may be formed of doped or P-doped spin-on-glass (SOG), PTEOS, or BPTEOS. Following planarization, e.g., chemical mechanical planarization (CMP) on the first ILD layer 26, a dielectric anti-reflective coating (DARC) or/and a bottom anti-reflectance coating (BARC) and a lithographically patterned photoresist layer are provided, which are omitted in the Figures for simplicity and clarity. A dry etching process is then carried out to form a first contact hole 28 that passes though the first ILD layer 26 and the CESL 24 so as to expose the silicide layer 22 positioned over the source/drain region 20. Then the patterned photoresist and the BARC layer are stripped. The depth of the first contact hole 28 is less than 1.5 times the height of the gate structure. As used throughout this disclosure, the term “aspect ratio” refers to a ratio of height to width of a contact hole. It will be appreciated that the first contact hole 28 may also be formed to expose the silicide layer 22 on the gate electrode layer 14, which is depicted in FIG. 2 and will be discussed afterward.

In FIG. 1B, a first conductive layer is deposited over the substrate 10 so that the first contact hole 28 is also filled. Portions of the first conductive layer other than the first contact hole 28 are removed by CMP. The first ILD layer 26 is therefore exposed and a remaining portion of the first conductive layer filling the first contact hole 28 becomes a first contact plug 30. The first contact plug 30 is formed of tungsten or tungsten-based alloy, and also named a tungsten plug 30 hereinafter. One method of forming the tungsten plug 30 includes a selective tungsten chemical vapor deposition (W-CVD) method. For example, tungsten may be deposited essentially only on silicon exposed at the bottom of the first contact hole 28, and overgrowth of tungsten may then be removed with an etch back step.

In FIG. 1C, an optional etch stop layer 32 and a second ILD layer 34 are deposited over the first ILD layer 26, and then a second contact hole 36 is patterned to pass through the second ILD layer 34 and the optional etch stop layer 32, exposing the top of the first contact plug 30. The optional etch stop layer 32 may be formed of silicon oxide, silicon nitride, silicon carbide, silicon oxynitride or combinations thereof, which may be formed through any of a variety of deposition techniques, including, LPCVD (low-pressure chemical vapor deposition), APCVD (atmospheric-pressure chemical vapor deposition), PECVD (plasma-enhanced chemical vapor deposition), PVD (physical vapor deposition), sputtering, and future-developed deposition procedures. Although the embodiment of the present invention illustrate the etch stop layer 32, the present invention provides value when omitting the use of the etch stop layer 32 depending on advances in contact formation control.

The second ILD layer 34 may be formed through any of a variety of techniques, including, spin coating, CVD, and future-developed deposition procedures. The second ILD layer 34 may be a single layer or a multi-layered structure (with or without an intermediate etch stop layer). In one embodiment, the second ILD layer 34 is formed of a low-k dielectric layer. As used throughout this disclosure, the term “low-k” is intended to define a dielectric constant of a dielectric material of 4.0 or less. A wide variety of low-k materials may be employed in accordance with embodiments of the present invention, for example, spin-on inorganic dielectrics, spin-on organic dielectrics, porous dielectric materials, organic polymer, organic silica glass, fluorinated silicate glass (FSG), diamond-like carbon, HSQ (hydrogen silsesquioxane) series material, MSQ (methyl silsesquioxane) series material, porous organic series material, polyimides, polysilsesquioxanes, polyarylethers, fluorosilicate glass, and commercial materials such as FLARE from Allied Signal or SiLK from Dow Corning, and other low-k dielectric compositions.

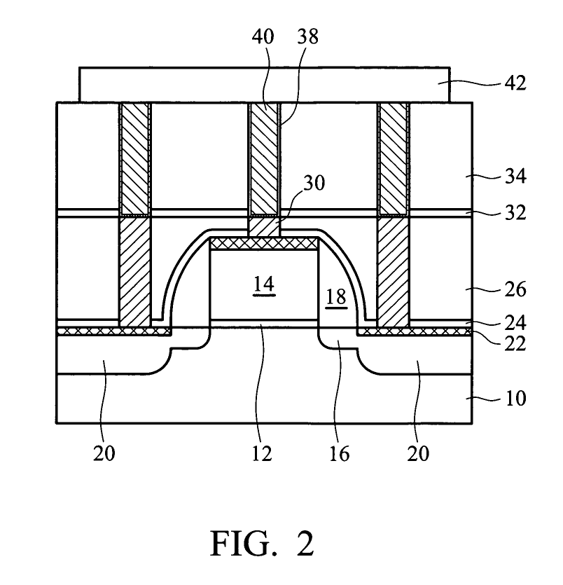

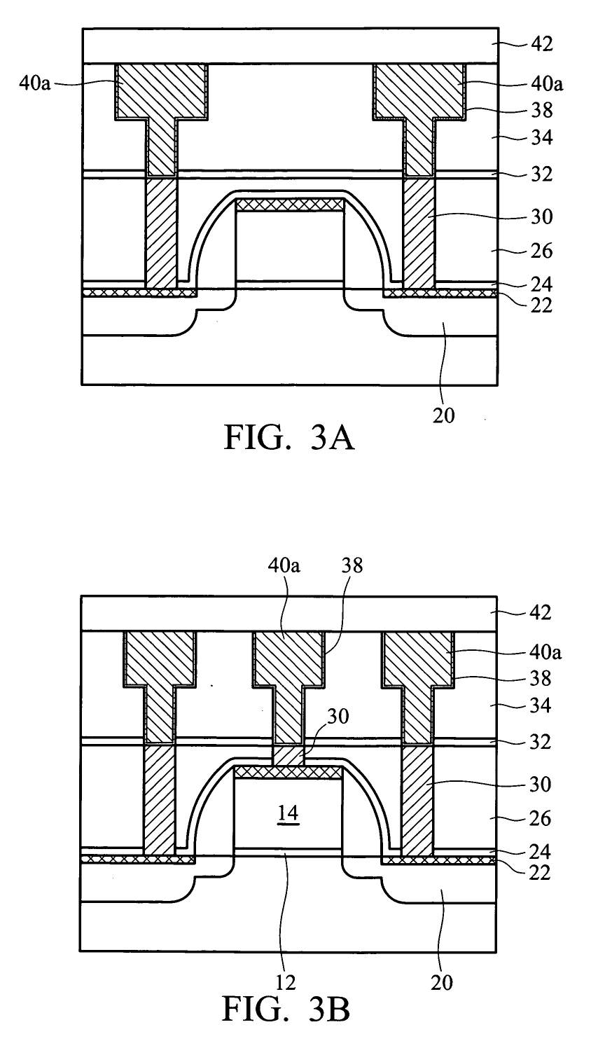

The second contact hole 36 may be a single-damascene opening or a dual-damascene opening formed using a typical lithographic with masking technologies and anisotropic etch operation (e.g. plasma etching or reactive ion etching). In one embodiment, the second contact hole 36 is a single-damascene opening as depicted in FIG. 1C, wherein the width of the second contact hole 36 may be equal to or greater than the width of the first contact hole 28. In other embodiment, the second contact hole 36 may be a dual-damascene opening including an upper trench section and a lower via hole section, which is depicted in FIG. 3A and FIG. 3B and will be discussed afterward.

In FIG. 1D, a diffusion barrier layer 38 is conformally deposited along the bottom and sidewalls of the second contact hole 36, thus providing both an excellent diffusion barrier in combination with good conductivity. A second conductive layer is then formed by means of electroplating methods for example, thus completely filling the second contact hole 36. The second conductive layer and the diffusion barrier layer 38 extended on to the second ILD layer 34 are then removed by means of CMP or other suitable etch back processes. Thus, a remaining portion of the second conductive layer filling the second contact hole 36 serves as a second contact plug 40. The diffusion barrier layer 38 may include, but is not limited to, a refractory material, TiN, TaN, Ta, Ti, TiSN, TaSN, W, WN, Cr, Nb, Co, Ni, Pt, Ru, Pd, Au, CoP, CoWP, NiP, NiWP, mixtures thereof, or other materials that can inhibit diffusion of copper into the second ILD layer 34 by means of PVD, CVD, ALD or electroplating. The second contact plug 40 may include a low resistivity conductor material selected from the group of conductor materials including, but is not limited to, copper and copper-based alloy. The second contact plug 40 also named a copper plug 40 hereinafter. For example, a copper-fill process includes metal seed layer deposition and copper electrochemical plating. The metal seed layer may include copper, nickel, molybdenum, platinum, or the like by means of PVD, CVD or ALD method.

Accordingly, a combination of the tungsten plug 30 and the copper plug 40 forms a staked contact structure to provide electrical coupling with the MOS transistor, such as desired one of source/drain regions 20 formed in a substrate 10 and/or the gate structure patterned on the substrate 10. Following formation of the stacked contact structure, an interconnection structure 42 may be deposited and patterned over the second ILD layer 34 to electrically couple the stacked contact structure, as shown in FIG. 1D.

In the stacked contact structure, the lower-level contact is the tungsten plug 30 formed in a first ILD layer 26, and the higher-level contact is the copper plug 40 formed in a second ILD layer 34. While the contact width continually decreases, the contact height can decrease proportionately to achieve a smaller aspect ratio, thus improving process window (e.g., photolithography and etching process window) in forming the tungsten plug 30 and being advantageously used in 90 nm, 65 nm, 45 nm technology or below. Also, since the copper plug 40 is a low electrical resistance material lower than that of the tungsten plug 30, the effective-contact resistance of the stacked contact structure can be reduced. In addition, the cumulative thickness of the first ILD layer 26 and the second ILD layer 34 can be increased to reduce the capacitance from the interconnection structure 42 to the gate electrode layer 14 and the capacitance from the interconnection structure 42 to the substrate 10, thus improving resistance/capacitance coupling (RC delay).

FIG. 2 is a cross-sectional diagram illustrating an exemplary embodiment of a stacked contact structure using a tungsten plug 30 stacked by a copper plug 40 for electrically coupling the gate electrode layer 14 and the source/drain regions 20, while explanation of the same or similar portions to the description in FIG. 1D is omitted herein.

FIG. 3A is a cross-sectional diagram illustrating an exemplary embodiment of a stacked contact structure using a tungsten plug 30 stacked by a dual-damascene copper plug 40a for electrically coupling the source/drain regions 20, while explanation of the same or similar portions to the description in FIG. 1D is omitted herein. In dual damascene techniques including a “via-first” patterning method or a “trench-first” patterning method, the upper trench section and the lower via hole section may be formed using a typical lithographic with masking technologies and anisotropic etch operation (e.g. plasma etching or reactive ion etching). A bottom etch stop layer, a middle etch stop layer, a polish stop layer, or an anti-reflective coating (ARC) layer may be optionally deposited on or intermediately in the second ILD layer 34, providing a clear indicator of when to end a particular etching process.

FIG. 3B is a cross-sectional diagram illustrating an exemplary embodiment of a stacked contact structure using a tungsten plug 30 stacked by a dual-damascene copper plug 40a for electrically coupling the gate electrode layer 14 and the source/drain regions 20, while explanation of the same or similar portions to the description in FIG. 3A is omitted herein.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A semiconductor device, comprising:
a gate structure on a semiconductor substrate;
a source/drain region laterally adjacent to said gate structure in said semiconductor substrate;
a first dielectric layer overlying said gate structure and said source/drain region, wherein said first dielectric layer has a first contact hole over at least one of said gate structure and said source/drain region;
a first contact plug formed of a first conductive material filling said first contact hole, wherein said first contact plug is electrically coupled to at least one of said gate structure and said source/drain region;
a second dielectric layer overlying said first dielectric layer and said first contact plug, wherein said second dielectric layer has a second contact hole exposing said first contact plug; and
a second contact plug formed of a second conductive material filling said second contact hole, wherein said second contact plug is electrically coupled to said first contact plug;
wherein, said second conductive material is different from said first conductive material, and said second conductive material has an electrical resistance lower than that of said first conductive material.

2. The semiconductor device of claim 1, wherein said first conductive material comprises tungsten or tungsten-based alloy.

3. The semiconductor device of claim 1, wherein said second conductive material comprises copper or copper-based alloy.

4. The semiconductor device of claim 1, wherein said second dielectric layer has a dielectric constant less than 4.0.

5. The semiconductor device of claim 1, further comprising:
a diffusion barrier layer along the bottom and sidewalls of said second contact hole, wherein said diffusion barrier layer is disposed between said second dielectric layer and said second contact plug.

6. The semiconductor device of claim 1, further comprising:
an etch stop layer between said first dielectric layer and said second dielectric layer, wherein said second contact hole passes through said second dielectric layer and said etch stop layer to expose the top of said first contact plug.

7. The semiconductor device of claim 1, further comprising:
silicide layers on said gate structure and said source/drain region respectively, wherein said first contact hole exposes at least one of said silicide layers on said gate structure and said source/drain region.

8. The semiconductor device of claim 7, further comprising:
a contact etch stop layer between said first dielectric layer and said silicide layer, wherein said second contact hole passes through said first dielectric layer and said contact etch stop layer to expose said silicide layer.

9. The semiconductor device of claim 1, wherein said second contact hole is a single-damascene opening or a dual-damascene opening.

10. The semiconductor device of claim 1, wherein the width of said second contact hole is equal to or greater than the width of said first contact hole.

11. The semiconductor device of claim 1, further comprising an interconnection structure overlying said second dielectric layer and electrically coupled to said second contact plug.

12. The semiconductor device of claim 1, wherein the depth of the first contact hole is less than 1.5 times the height of the gate structure.

13. A semiconductor device, comprising:
a gate structure on a semiconductor substrate;
source/drain regions laterally adjacent to said gate structure in said semiconductor substrate;
a first dielectric layer overlying said gate structure and said source/drain regions, wherein said first dielectric layer has a first contact hole over at least one of said gate structure and said source/drain regions;
a tungsten plug formed in said first contact hole and electrically coupled to at least one of said gate structure and said source/drain regions;
a second dielectric layer overlying said first dielectric layer and said first contact plug, wherein said second dielectric layer has a second contact hole exposing said tungsten plug;
a copper plug formed in said second contact hole and electrically coupled to said tungsten plug; and
an interconnection structure overlying said second dielectric layer and electrically coupled to said copper plug.

14. The semiconductor device of claim 13, wherein said second dielectric layer has a dielectric constant less than 4.0.

15. The semiconductor device of claim 13, further comprising a diffusion barrier layer along the bottom and sidewalls of said copper plug.

16. The semiconductor device of claim 13, further comprising:
an etch stop layer between said first dielectric layer and said second dielectric layer, wherein said second contact hole passes through said second dielectric layer and said etch stop layer to expose the top of said tungsten plug.

17. The semiconductor device of claim 13, further comprising:
silicide layers on said gate structure and said source/drain region respectively, wherein said first contact hole exposes at least one of said silicide layers on said gate structure and said source/drain region.

18. The semiconductor device of claim 17, further comprising:
a contact etch stop layer between said first dielectric layer and said silicide layer, wherein said second contact hole passes through said second dielectric layer and said contact etch stop layer to expose said silicide layer.

19. The semiconductor device of claim 1, wherein said second contact hole is a single-damascene opening or a dual-damascene opening.

20. The semiconductor device of claim 1, wherein the width of said second contact hole is equal to or greater than the width of said first contact hole.
